(19) United States
(12) Patent Application Publication
(10) Pub. No.: US 2012/0325995 A1
(43) Pub. Date: Dec. 27, 2012

(54) DEVICE AND ITS USE FOR HOLDING A COMPUTING DEVICE

(76) Inventor: Jerald M. BALESTRINO, Hubbard, OH (US)

(21) Appl. No.: 13/532,427

(22) Filed: Jun. 25, 2012

Related U.S. Application Data
(60) Provisional application No. 61/500,536, filed on Jun. 23, 2011.

(51) Int. Cl. H05K 7/00

(52) U.S. Cl. 248/274.1; 248/309.1; 248/316.7; 248/310

(57) ABSTRACT

Provided is a device and its use for holding a computing device. The device can be used is a sitting or laying position to hold the CD by putting the device around one or more bend knees.

### CROSS-REFERENCE

This application claims the benefit of U.S. Provisional Application No. 61/500,536, filed on Jun. 23, 2011, whose content is incorporated herein by reference in its entirety. As Jun. 23, 2012 falls on a Saturday, this application is considered timely filed on Jun. 25, 2012, the following Monday.

### BACKGROUND SECTION OF THE INVENTION

Using a mobile or portable computing device (CD), such as a laptop computer or a tablet computer, can be challenging in a sitting or laying position. For example, it is hard to use a CD while sitting comfortably on a sofa or laying in bed. The CD can weigh several pounds and needs to be held at all times.

U.S. 2009/0229479, U.S. Pat. No. 5,937,765, U.S. Pat. No. 6,663,072, and U.S. Pat. No. 6,883,694 propose placing the CD on the lap. However, when placing the CD on the lap, it is difficult to access keys and the mouse pad, and a user has to sit in an upright position. US2007/0221696 proposes a complicated brief case in which a user's feet have to be maintained in the same position, allowing for little movement of the feet.

There is a need in the art for a device that allows using a CD without constantly holding the CD in a comfortable position.

### SUMMARY OF THE INVENTION

Provided is a device for holding a portable computing device (CD) comprising
a) a strap with two ends for placing around an object;
b) one or more holders attached to each end of the strap for holding the portable CD;
wherein the strap is put around an object to support the portable CD placed in the holder.

The object can be one or more knees of a person in a bent position. The device can comprise a pad to cushion the strap while resting on the object. The pad can be a knee pad. The holder can be a clip or a clamp. The portable CD can be a tablet computer or a laptop computer. The length of the strap can be adjusted. The strap can have a length of about 15 inches to about 50 inches. The device can comprise an additional strap that wraps around the CD. The additional strap can be attached in a substantially perpendicular fashion to the main or original strap. The additional strap can comprise two straps with female and male parts. The CD can be held from bottom. A single holder can be attached to both ends of the strap. The width of a single holder can be about 2 to about 5 inches wide. Each end of the strap can be attached to a holder, for a total of two.

Provided is a method of holding a CD comprising holding the CD with the device described herein.

### BRIEF DESCRIPTION OF THE FIGURES

FIG. 1 is an illustration of person using the device by suspending a laptop from the knee in a sitting position.

FIG. 2 is a side view illustration of person using the device by suspending a laptop from the knee in a sitting position.

FIG. 3 is an illustration of the device with the shorter side of the clips facing the front.

FIG. 4 is an illustration of the device with the shorter side of the clips facing the back.

FIG. 5 is an illustration of the device with optional side straps that wrap around the CD.

FIG. 6 is an illustration of the device with the strap connected to a single wide clip.

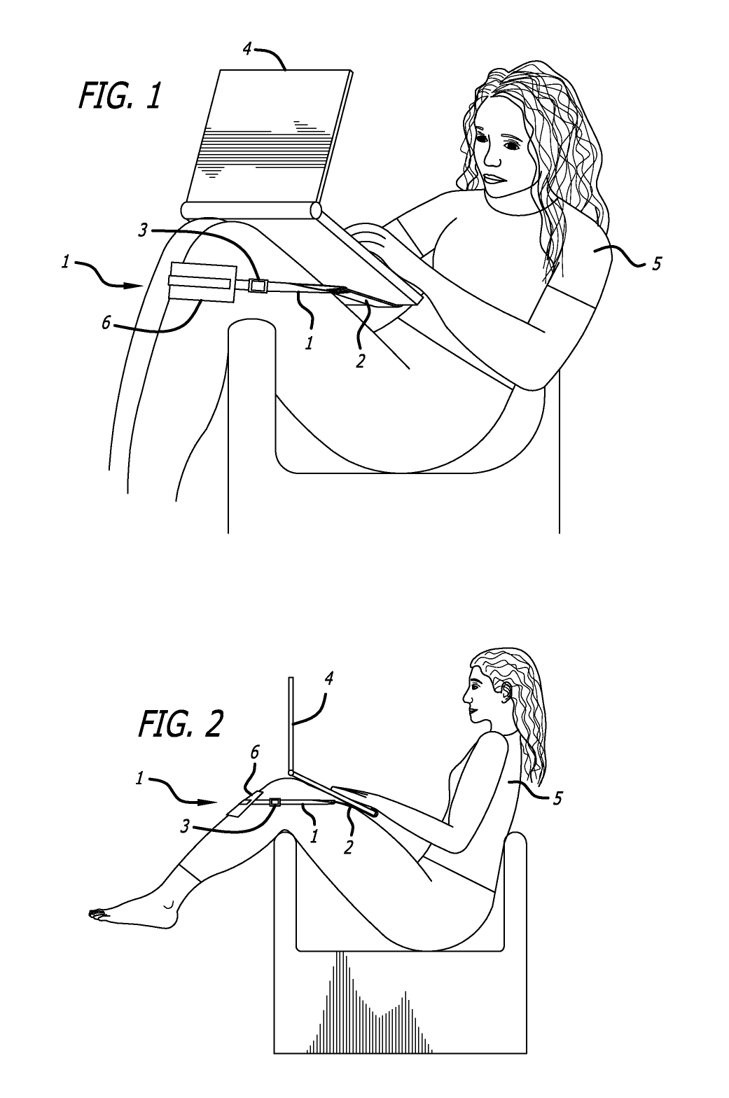

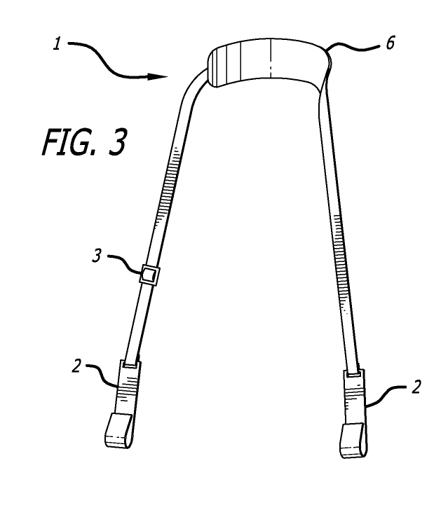

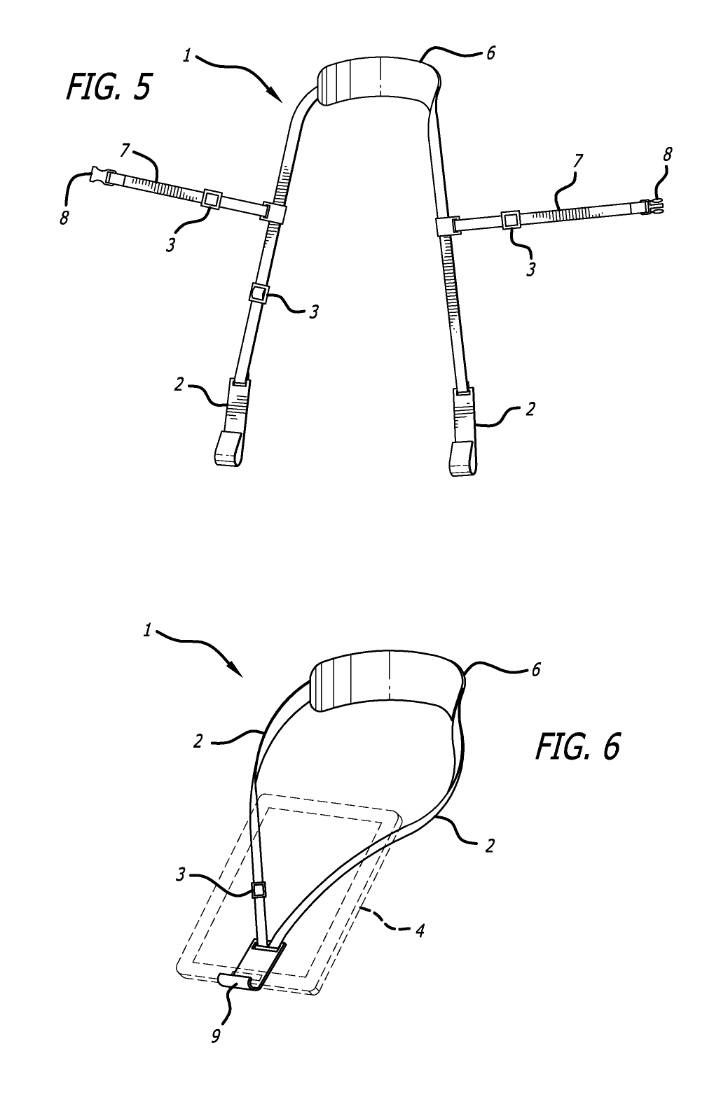

### DETAILED DESCRIPTION OF THE INVENTION

The present invention provides a device that allows for suspending a CD (4) such as a laptop or tablet from an object, particularly a user's (5) bent knee. The CD's (4) weight is supported by the device, and a user (5) can enjoy the CD (4) in a comfortable position without the use of a table.

The device includes a strap (1) that can wrap around one or both knees, and preferably on holder (2) at each end of the strap (1) of a total of two clips (2). A knee pad (6) can be attached to the strap (1) for comfort.

The strap (1) can be made from any material that can wrap around the knee and support the weight of the CD (4). Examples of materials for the strap (1) include nylon, rope, plastic, or cotton. The strap (1) can also be made from an elastic material.

The strap (1) is a suitable size to around one or both knees. In one embodiment, the strap (1) length can adjust from about 15 inches to about 28 inches without the additional length of the clip (2). In another embodiment, the strap (1) is from about 15 inches to about 50 inches. In one embodiment, with the clip (2) length included, the overall length can be about 23 inches to about 36 inches. The strap can be a single piece or multiple pieces, and can have ends that are connected to the clip on one end, and joined in a circular or oval pattern at the other end (a preformed closed loop).

The strap (1) can be any width desired that gives enough strength to support the CD (4) and/or providing a comfortable experience. The strap (1) can have a single constant width or variable width. With a variable width, the portion that rests on the knee can for example be wider. The larger width may provide greater comfort when the strap (1) is resting against the knee.

For comfort, a pad (6), particularly a knee pad (6), can be added to the strap (1). The knee pad (6) can be made from foam, rubber, doth, synthetic or other suitable materials. Suitable materials include those that give comfort and/or grip on the knee. The knee pad (6) can be about 3 inches to 10 inches long and about 2 to 3 inches wide. The knee pad (6) can have slits to allow the strap (1) to slide through and for adjustments.

The device has one or more holders (2) that hold the CD (4). There can be a single holder (9) attached to both ends of the strap (1). Alternatively, each end of the strap (1) can be attached to its own holder (2). The holder (2, 9) can for example be a clip (2) or a clamp, and any shape that supports the CD (4). The clips (2) can be in a ‘J’ shape with a narrow neck. The clips (2) can also be in “u” shape. Preferably the clip (2) engages the CD (4) and provides a secure hold of the CD (4). The holder (2) can be made from metal, rubber or any type of material that gives superior mechanical properties, such as strength, support and flexibility. The holder (2) can be made by injection molding. The holder (2) can have a foam inlay that offers grip and protection for the laptop. The inlay can also be made from cloth, rubber, or any material that allows for securing the CD (4). In place of holder (2), clamps can also be used. The clamps can be made of a strong plastic that flex to allow holding CDs (4) with various sizes, such as laptops and tablets and book readers. With the use of a tight clamp and even a clip, it is possible to hold the CD (4) from side or top, rather than resting the CD (4) on the bottom,

In one embodiment, the clip has a width of about one inch, a maximum height of about 4 inches, a width of about one inch, and a thickness of about 0.01 inch. These parameters can be varied depending on the CD (4). For example, the width can be about 2 to about 5 inches, particularly when a single clip is used (9) to attach to both ends of the strap (1). It is also possible to just have one clip of about 5 or 6 inches wide (9) (and a shorter height) to accommodate a smaller tablet computers. The maximum height of the clip can for example be about 1 to about 2 inches.

In one embodiment, the holder (2) has an opening that allow for attachment of the strap (1). The strap (1) is looped around the opening of the holder, such as a clip (2). The strap (1) that is looped around can be attached to another part of the strap (1) to secure the loop. The attachment can also be done with an adjuster (3) to allow for adjustment of size of the strap (1). One or two adjusters (3) can be used. The typical adjuster (3) is an eight shaped boxed figure that allows for looping the strap (1) and adjusting the loop size.

The strap (1) can have an adjuster (3) that allows for adjusting the length of the strap (1). The adjuster (3) can use any mechanism. It can be an eight shaped box figure. The strap (1) can be fastened to one clip (2, 9) and then looped through the other and then slides through the adjuster (3). Two adjusters (3) can also be used on either ends too.

The device can have an additional optional feature (7), which is an additional strap which wraps around device to hold the computing device securely. The additional strap (7) can be attached to the original strap to which the clips (2) are attached. In one embodiment, the additional strap (7) is substantially perpendicular to the original strap (1). The additional straps (7) can have a male and a female part (8). One or both of the additional straps wrap around the CD (4) and reversibly lock to each other to hold the CD (4) securely. The additional strap (7) can be made of same or different material than the original strap. The additional strap can be made of elastic material.

In one embodiment, the device is assembled by attaching one end of the strap (1) to one of the “J” shaped clips. The strap (1) then slides through a knee pad (6), then an adjuster (3) and then loops around an opening in the other clip. The strap (1) loops back on itself back through the adjuster (3), allowing for lengthening or loosening (adjusting size).

The device can work by using the clips (2) to attach or suspend to the bottom (front edge) of the CD (4) and using the strap (1) to suspend it from the knee or knees. The clips (2) are hooked to the front edge of the laptop/tablet they can be slid along the bottom to give the perfect fit for the user (5). This then creates a “loop” with the strap (1).

Also provided is a method for using the device. The method can include in one embodiment attaching one clip to the left side of the front edge of the CD (4) and one clip to the right side of the front edge of the CD (4). The user (5) then lies back on a couch or bed or floor and one or more of their knees bent. The result is that the CD (4) is suspended from one more of the knees and is allowed to rest on the users (5) thighs.

What is claimed is:

1. A device for holding a portable computing device (CD) comprising:
a) a strap with two ends for placing around an object;
b) one or more holders attached to each end of the strap for holding the portable CD;
wherein the strap is put around an object to support the portable CD placed in the holder.

2. The device of claim 1, wherein the object is one or more knees of a person in a bent position.

3. The device of claim 1, further comprising a pad to cushion the strap while resting on the object.

4. The device of claim 3, wherein the pad is a knee pad.

5. The device of claim 1, wherein the holder is a clip.

7. The device of claim 1, wherein the portable CD is a tablet computer.

8. The device of claim 1, wherein the portable CD is a laptop computer.

9. The device of claim 1, wherein the length of the strap can be adjusted.

10. The device of claim 1, wherein the strap has a length of about 15 inches to about 50 inches.

11. The device of claim 1, further comprising an additional strap attached to the strap of claim 1, wherein the additional strap wraps around the CD.

12. The device of claim 11, wherein the additional strap is attached in a substantially perpendicular fashion to the strap of claim 1.

13. The device of claim 11, wherein the additional strap comprises of two straps with female and male parts.

14. The device of claim 1, wherein the CD is held from bottom.

15. The device of claim 1, wherein a single holder is attached to both ends of the strap.

16. The device of claim 15, wherein width of the holder is about 2 to about 5 inches wide.

17. The device of claim 1, wherein each end of the strap is attached to a single holder, for a total of two holders.

18. A method of holding a CD comprising holding the CD with the device of claim 1.
